(19) United States
(12) Patent Application Publication
(10) Pub. No.: US 2015/0192613 A1
(43) Pub. Date: Jul. 9, 2015

(54) ELECTRICAL CONNECTOR

(71) Applicant: KONINKLIJKE PHILIPS N.V., EINDHOVEN (NL)

(72) Inventors: Maurice Herman Johan Draaijer, Ittervoort (NL); Bozena Erdmann, Aachen (DE); Michael Alex Van Hartskamp, Eindhoven (NL); Matthias Wendt, Wurselen (DE); Manuel Eduardo Alarcon-Rivero, Delft (NL)

(21) Appl. No.: 14/367,628

(22) PCT Filed: Dec. 21, 2012
(86) PCT No.: PCT/IB2012/057606

§ 371 Date: Jun. 20, 2014

Related U.S. Application Data
(60) Provisional application No. 61/578,939, filed on Dec. 22, 2011.

(51) Int. Cl. G01R 1/067; G01R 31/00

(52) U.S. Cl. CPC G01R 1/06711; G01R 31/00

(57) ABSTRACT

The invention relates to an electrical connector (1) for connecting an electrical device to an electrical conductor (3) for powering the electrical device with DC voltage. The electrical connector comprises a diagnostic information providing unit for providing diagnostic information about a connection between the electrical device and the electrical conductor and an indicator for indicating the determined diagnostic information. An installer can therefore readily see whether the electrical connection is correct or not. Accordingly, the installer can modify the electrical connections such that the indicated determined diagnostic information indicates a correct electrical connection. This reduces the likelihood of a shutdown of the powering of the electrical device with DC voltage, after the installation has been completed.

### FIELD OF THE INVENTION

The invention relates to an electrical connector for connecting an electrical device to an electrical conductor for powering the electrical device with direct current (DC) voltage.

### BACKGROUND OF THE INVENTION

A low voltage DC power distribution system is known from the EMerge standard. The DC power distribution system comprises power rails to which electrical devices, i.e. electrical loads, like lighting fixtures can be attached by using corresponding electrical connectors. If the electrical devices are wrongly connected to the power bar, for instance, if an electrical device is connected requiring power being larger than the maximum power, which can maximally be provided by the power rail, the DC power distribution system will be shut down after installation.

### SUMMARY OF THE INVENTION

It is an object of the present invention to provide an electrical connector for connecting an electrical device to an electrical conductor for powering the electrical device with DC voltage, wherein the likelihood of a shutdown of the powering with the DC voltage can be reduced.

In a first aspect of the present invention an electrical connector for connecting an electrical device to an electrical conductor for powering the electrical device with DC voltage is presented, wherein the electrical connector comprises:
a diagnostic information providing unit for providing diagnostic information about a connection between the electrical device and the electrical conductor, and
an indicator for indicating the determined diagnostic information.

Since the diagnostic information providing unit provides diagnostic information about the connection between the electrical device and the electrical conductor and since this diagnostic information is indicated, an installer can readily see whether the electrical connection is correct or not. Accordingly, the installer can modify the electrical connections such that the indicated determined diagnostic information indicates a correct electrical connection. This reduces the likelihood of a shutdown of the powering of the electrical device with DC voltage, after the installation has been completed.

The diagnostic information providing unit is preferentially a diagnostic information determining unit for determining the diagnostic information. It can be a correspondingly adapted electrical circuit. The diagnostic information is preferentially information, which characterizes the electrical connection and which can be influenced by modifying the electrical connection itself and/or by modifying the electrical device, in particular, by replacing the electrical device by another electrical device.

The electrical conductor is preferentially a power rail, and the electrical device is, for example, a lamp like a fluorescent lamp, a light emitting diode, a sensor, a game console et cetera.

It is preferred that the diagnostic information providing unit is adapted to determine diagnostic information being indicative of at least one of polarity correctness, power availability, power losses, and correctness of voltage level. Thus, the diagnostic information can be, for instance, whether the polarity is correct and/or whether sufficient power is available. For instance, after the diagnostic information providing unit has checked the polarity correctness, the indicator can indicate that the polarity is correct or wrong, respectively, for example, by acoustical or optical signals, or by reporting it over a communication interface like powerline communication (PLC), visual light communication (VLC), wireless communication, for instance, BACnet, KNX, 802.15.4/ZigBee, 802.15.4/6LoWPAN, 802.1 MP, et cetera.

For determining whether the polarity is correct the diagnostic information providing unit can be adapted to, for instance, measure a current flowing through a diode or to measure a voltage with an integrated circuit consisting of at least an integrator diode and resistors.

For determining the power availability the diagnostic information providing unit can be adapted to determine, for instance, that the electrical device, which should be connected to the electrical conductor via the electrical connector, requests more power than available, or that sufficient power can be provided by the electrical conductor, i.e., for instance, sufficient power is on the bus bar or the required power is smaller than the maximal power that can be provided by the electrical conductor.

The indicator can indicate a single kind of diagnostic information like whether the polarity is correct or not, and/or the indicator can give an indication being indicative of a combination of different kinds of diagnostic information. In a preferred embodiment, the indicator is adapted to indicate that an installation of the electrical connector has been completed successfully, if the diagnostic information meets predefined installation completed conditions. Thus, the indicator can directly show diagnostic information, or it can indicate the diagnostic information indirectly by indicating whether the diagnostic information meets predefined installation completed conditions. For instance, the predefined installation completed conditions can define that the installation is successfully completed, if the polarity is correct and the electrical device does not request more power than available. The indicator can be adapted to, for example, show a red light, if the polarity is wrong and/or sufficient power is not available, and a green light, if the polarity is correct and enough power is available.

Preferentially, the electrical conductor is electrically connected to a DC voltage source, wherein the DC voltage source is adapted to be switched off, if an overload condition is detected, wherein the diagnostic information providing unit is adapted to check whether a 0 V condition is present on the electrical conductor, after an electrical load has been applied to the electrical conductor, wherein the load corresponds to the power requested by the electrical device to be connected by the electrical conductor, and to determine the power availability based on whether the 0 V condition is present. In particular, the diagnostic information providing unit can measure whether there is a 0 V condition, immediately after the electrical load has been applied to the electrical conductor. The electrical load applied for the power availability check can be a fixed load which corresponds to the maximum or typical power consumption of the electrical device to be connected. The electrical connector can also comprise an input unit for allowing a user to set the electrical load applied for the power availability check.

The electrical load for checking power availability can be part of the electrical connector, in particular, of the diagnostic information providing unit, itself. For instance, a corresponding test load circuit can be part of the diagnostic information providing unit. In the case of the electrical connector being connected to a load, i.e. an electrical device like a lamp, this load can be used as a test load, for instance, by gradually ramping up the load power consumption. Power availability can also be determined as known in the art, for instance, by a circuit, being part of the electrical connector itself, comprising at least a resistor, and a diode can be used to indicate power availability, and/or it can be communicated via a communication interface.

In other embodiments, the diagnostic information providing unit can also be adapted to determine the power availability in another way. In a preferred embodiment, the diagnostic information providing unit is adapted to determine the power availability based on a measurement of an increase of a total current on the electrical conductor and a detection of overcurrent. For measuring the total current the electrical connector is preferentially placed close to a feed connector connecting the electrical conductor with the DC voltage source. Or, the feed connector supplying power to the electrical conductor or the DC voltage source could, instead of shutting down, provide an indication, for instance, via a defined power supply change like a voltage drop of, for instance, 5 V or a communication signal, which can be received by the diagnostic information providing unit, wherein the indication can be shown by the indicator. Moreover, the diagnostic information providing unit can be adapted to measure a drop over the electrical conductor, in particular, over a power bar conductor, over a fixed distance of, for instance, 5 cm, for determining the current. The diagnostic information providing unit can also be adapted to measure the current magnetically by measuring a magnetic field strength at a predefined distance from the electrical conductor. Thus, the diagnostic information providing unit can be adapted to measure the magnetic field strength at a fixed distance of, for instance, 0.1 mm from the electrical conductor which is also directly current related. The diagnostic information providing unit can be adapted to use the giant magnetoresistive (GMR) effect, i.e. the diagnostic information providing unit can comprise a GMR sensor for measuring the current. Furthermore, the diagnostic information providing unit can comprise two GMR sensors for measuring the current on both sides of the electrical connector. This allows the diagnostic information providing unit to determine from which side the current is coming and which difference the electrical device connected with this electrical connector is making. Also this diagnostic information can be shown by the indicator.

In an embodiment, the electrical connector comprises a power supply for supplying power to the diagnostic information providing unit and the indicator. The power supply is, for instance, a battery, a capacitor, et cetera. This allows the electrical connector to be operated, even if the electrical conductor is in a 0 V condition.

The electrical connector can comprise a cable for electrically connecting the electrical device to the electrical conductor, or it can be integrated into the electrical device. In particular, the electrical connector can be integrated into a housing of the electrical device. This allows directly connecting the electrical device to the electrical conductor, without using a cable for this connection.

Moreover, the electrical connector can comprise an input unit for allowing a user to input a request for determining and indicating the diagnostic information. The input unit comprises, for instance, at least one of a push button, a dip switch, a slider, et cetera, wherein the electrical connector is adapted to determine and indicate the diagnostic information, if, for example, the user presses the push button.

In an embodiment, the electrical connector further comprises an assignments providing unit for providing assignments between a) at least one of determination procedures for determining diagnostic information and indication procedures for indicating diagnostic information and b) conditions, and a condition providing unit for providing an actual condition, wherein at least one of the diagnostic information providing unit and the indicator are adapted to perform a determination procedure and an indication procedure, respectively, in accordance with the provided actual condition and the provided assignments. The assignments providing unit can be a storing unit in which predefined assignments are stored already, or a receiving unit for receiving the assignments via a wired or wireless data connection. The condition providing unit can be a measuring unit for measuring the respective actual condition. The condition is, for example, an overload condition at the electrical conductor to which the electrical connector is connected. This allows the electrical connector to indicate diagnostic information, only if the diagnostic information is really relevant.

The indicator is preferentially is adapted to optically and/or acoustically indicate the diagnostic information. For instance, the indicator can comprise one or several light emitting diodes for indicating the diagnostic information by using colors.

In a further aspect of the present invention an electrical device to be electrically connected with an electrical conductor to be powered by DC voltage is presented, wherein the electrical device comprises the electrical connector as defined in claim 1.

In a further aspect of the present invention a diagnosis apparatus for providing diagnostic information regarding an electrical connection between an electrical device and an electrical conductor for powering the electrical device with DC voltage by an electrical connector is presented, wherein the diagnosis apparatus comprises a diagnostic information providing unit for providing diagnostic information about a connection between the electrical device and the electrical conductor and an indicator for indicating the determined diagnostic information. Thus, a separate diagnostic apparatus can be provided, which is not adapted for connecting an electrical device, but only for monitoring/checking purposes.

In a further aspect of the present invention a method for providing diagnostic information regarding an electrical connection between an electrical device and an electrical conductor by an electrical connector as defined in claim 1 for powering the electrical device with DC voltage is presented, the method including the steps of providing diagnostic information about a connection between the electrical device and the electrical conductor by a diagnostic information providing unit, and indicating the determined diagnostic information by an indicator.

In a further aspect of the present invention a computer program for providing diagnostic information regarding an electrical connection between an electrical device and an electrical conductor by an electrical connector as defined in claim 1 for powering the electrical device with DC voltage is presented, wherein the computer program comprises program code means for causing the electrical connector to carry out the steps of the method for providing diagnostic information as defined in claim 14, when the computer program is run on a computer controlling the electrical connector.

It shall be understood that the electrical connector of claim 1, the electrical device of claim 12, the diagnosis apparatus of claim 13, the method of claim 14 and the computer program of claim 15 have similar and/or identical preferred embodiments, in particular, as defined in the dependent claims.

It shall be understood that a preferred embodiment of the invention can also be any combination of the dependent claims with the respective independent claim.

These and other aspects of the invention will be apparent from and elucidated with reference to the embodiments described hereinafter.

### BRIEF DESCRIPTION OF THE DRAWINGS

In the following drawings:

FIG. 1 shows schematically and exemplarily an embodiment of a DC power distribution system,

FIG. 2 shows schematically and exemplarily details of connections within the DC power distribution system,

FIG. 3 shows schematically and exemplarily an embodiment of an electrical conductor,

FIG. 4 shows schematically and exemplarily electrical connections within another DC power distribution system,

FIG. 5 shows schematically and exemplarily a further embodiment of an electrical conductor, and

FIG. 6 shows a flowchart exemplarily illustrating an embodiment of a method for providing diagnostic information regarding an electrical connection between an electrical device and an electrical conductor by an electrical connector for powering the electrical device with DC voltage.

### DETAILED DESCRIPTION OF EMBODIMENTS

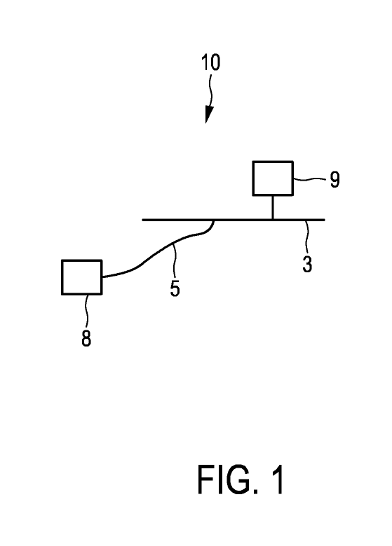

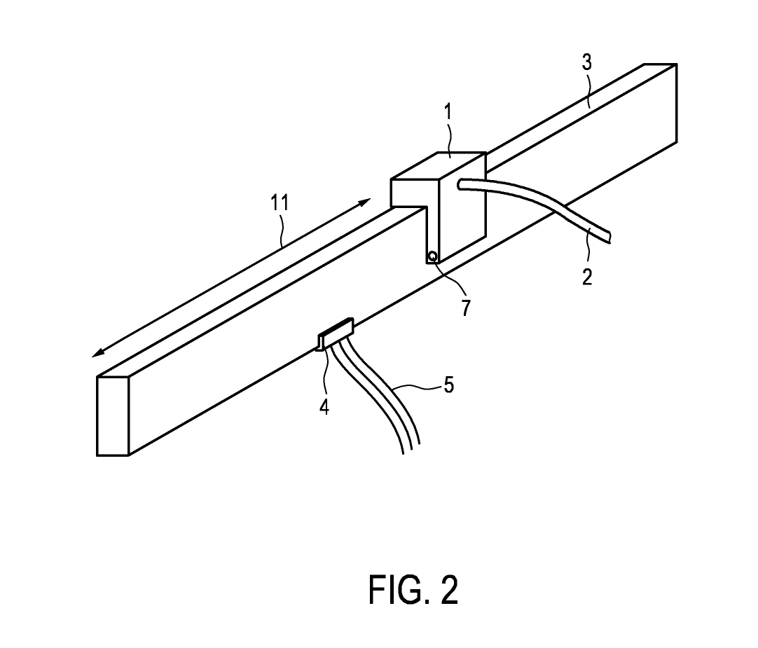

FIG. 1 shows schematically and exemplarily a DC power distribution system comprising a DC voltage source 8 being connected to an electrical conductor 3 via a cable 5, and an electrical device 9 like a lamp being connected to the electrical conductor 3. The connections are exemplarily and schematically shown in more detail in FIG. 2.

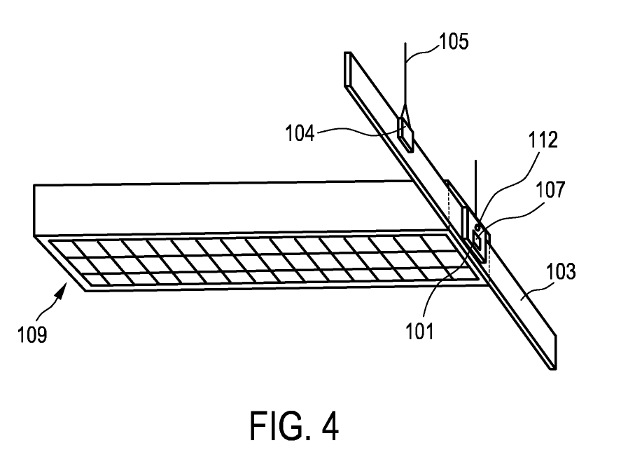

The cable 5 is electrically connected to the electrical conductor 3 via a feed connector 4, and the electrical device 9 is connected to the electrical conductor 3 via an electrical connector 1 and a further cable 2. The feed connector 4 is preferentially located at one third of the length of the electrical conductor 3. The electrical connector 1 is located on the electrical conductor 3 with a distance 11 from an end of the electrical conductor 3. The electrical connector 1 can be attached via the cable 2 to the electrical device 9 as shown in FIG. 2, or the electrical connector 1 can be integrated with an electrical device as will be explained further below with reference to FIG. 4.

In this embodiment, the electrical conductor 3 is a power rail, wherein the connections can be, for instance, with an internal or external bus bar of the power rail.

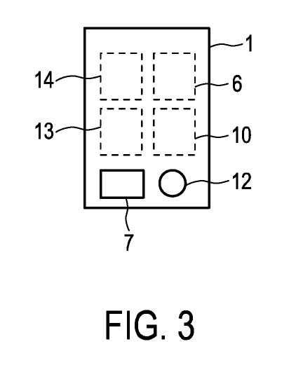

The electrical connector 1 comprises a diagnostic information providing unit 6 for providing diagnostic information about the connection between the electrical device and the electrical conductor and an indicator 7 for indicating the determined diagnostic information as schematically and exemplarily shown in FIG. 3. The diagnostic information providing unit 6 is, in this embodiment, a diagnostic information determining unit for determining the diagnostic information. It comprises preferentially a correspondingly adapted electrical circuit. It is preferentially adapted to determine diagnostic information being indicative of at least one of polarity correctness, power availability, power losses and correctness of voltage level.

For determining whether the polarity is correct the diagnostic information providing unit 6 can be adapted to, for instance, measure a current flowing through a diode of the electrical connector, in particular, of the diagnostic information providing unit, or to measure a voltage with an integrated circuit consisting of at least one integrator diode and resistors. Also other techniques can be used for checking for the correct polarity. The polarity check can preferentially be performed without communication with the power rail.

After the diagnostic information providing unit 6 has checked the polarity correctness, the indicator 7 can indicate whether the polarity is correct or wrong by acoustical and/or optical signals. For example, the indicator 7 can be adapted to provide a red light, if the polarity is wrong, and to provide a green light, if the polarity is correct. Also other colors can of course be used for indicating the diagnostic information. In addition or alternatively, different tones can be used for indicating the diagnostic information. For instance, a first tone can be used, if the polarity is wrong, and a second tone can be used, if the polarity is correct.

In another embodiment, the indicator can be adapted to report the determined polarity over a communication interface like PLC, VLC, wireless communication, et cetera to another unit, wherein the other unit can be adapted to show the result of the check for polarity correctness to a user.

For determining the power availability the diagnostic information providing unit 6 is adapted to determine whether the electrical device 9, which has been connected to the electrical conductor 3 via the electrical connector 1, requests more power than available, or whether sufficient power can be provided by the electrical conductor. Thus, the power available on the power rail 3 can be compared with the power required by the electrical device 9 for checking for power availability. In particular, the power available on the power rail 3 can be compared with the maximally required power of the electrical device 9.

Moreover, the DC voltage source 8 can be adapted to be switched off, if an overload condition is detected, wherein the diagnostic information providing unit 6 can be adapted to check whether a 0 V condition is present on the electrical conductor 3, after an electrical load, which corresponds to the power requested by the electrical device 9, has been applied to the electrical conductor 3 and to determine the power availability based on whether the 0 V condition is present. The electrical load applied for the power availability check can be a fixed load which corresponds to the maximum or typical power consumption of the electrical device to be connected. The electrical connector can also comprise an input unit like a little keyboard, sliding elements, setting wheels et cetera for allowing a user to set the electrical load applied for the power availability check.

Generally, the diagnostic information providing unit can be adapted to apply a predefined load value, to measure the behavior of the power rail, after the predefined load value has been applied, and to determine power availability depending on the measured behavior. As indicated above, overloading of a power rail, in particular, of a bus bar, can be discovered by the voltage source, which can also be regarded as being a power supply module and which provides the DC voltage to the power rail, wherein the DC voltage source is temporarily disconnected, after the overloading has been discovered. Thus, if the diagnostic information providing unit comprises a power limit check circuit measuring a 0 V condition immediately after applying the load, in particular, once or repetitively, it can remove the load and the overload condition can be indicated by the indicator 7, thereby indicating that there is not sufficient power on the power rail for the electrical device to be connected.

The electrical load for checking power availability can be part of the electrical connector, in particular, of the diagnostic information providing unit, itself. For instance, a corresponding test load circuit can be part of the diagnostic information providing unit. In the case of the electrical connector being connected to a load, i.e. an electrical device like a lamp, this load can be used as a test load, for instance, by gradually ramping up the load power consumption. In other embodiments, the diagnostic information providing unit 6 can also be adapted to determine the power availability in another way.

For instance, the diagnostic information providing unit 6 can be adapted to determine the power availability based on a measurement of an increase of a total current on the electrical conductor and a detection of overcurrent. For measuring the total current the electrical connector is preferentially placed close to the feed connector connecting the electrical conductor with the DC voltage source. Or, the feed connector supplying power to the electrical conductor or the DC voltage source could, instead of shutting down, provide an indication, for instance, via a defined power supply change like a voltage drop of, for instance, 5 V or a communication signal, which can be received by the diagnostic information providing unit, wherein the indication can be shown by the indicator. Moreover, the diagnostic information providing unit can be adapted to measure a drop over the electrical conductor, in particular, of a power bar conductor, over a fixed distance of, for instance, 5 cm, for determining the current. The diagnostic information providing unit can also be adapted to measure the current magnetically by measuring a magnetic field strength at a predefined distance from the electrical conductor. Thus, the diagnostic information providing unit can be adapted to measure the magnetic field strength at a fixed distance of, for instance, 0.1 mm from the electrical conductor which is also directly current related. The diagnostic information providing unit can be adapted to use the GMR effect, i.e. the diagnostic information providing unit can comprise a GMR sensor for measuring the current. Furthermore, the diagnostic information providing unit can comprise two GMR sensors for measuring the current on both sides of the electrical connector 1. This allows the diagnostic information providing unit to determine from which side the current is coming and which difference the electrical device connected with this electrical connector is making. Also this diagnostic information can be shown by the indicator.

In this embodiment, the electrical connector 1 further comprises an internal power supply 10 for supplying power to the diagnostic information providing unit 6 and the indicator 7. The internal power supply is, for instance, a battery, a capacitor, et cetera. This allows providing the diagnostic information and indicating the diagnostic information while there is no voltage on the power rail 3.

The indicator 7 is preferentially adapted to indicate that an installation of an electrical device 9 via the electrical connector 1 has been completed successfully, if the diagnostic information meets predefined installation completed conditions. For instance, the predefined installation completed conditions can define that the installation is successfully completed, if the polarity is correct and the electrical device does not request more power than available. The indicator 7 can be adapted to show a red light, if not all predefined installation completed conditions are fulfilled, and to show a green light, if all predefined installation completed conditions are fulfilled. The indicator 7 can also be adapted to indicate whether the predefined installation completed conditions are met by the diagnostic information or not by using other optical indicators and/or by using acoustical indicators.

Moreover, the electrical connector 1 comprises an input unit 12 for allowing a user to input a request for determining and indicating the diagnostic information. In this embodiment, the input unit 12 comprises a push button, wherein the electrical connector 1 is adapted to determine and indicate the diagnostic information, if the push button 12 is pressed. Thus, the checks may be performed and the resulting diagnostic information may be indicated on request, but not necessarily constantly. However, the diagnostic information providing unit 6 and the indicator 7 can also be adapted such that selected checks and/or selected indications can be triggered automatically by certain conditions discovered during operation like a bus bar overload, which may occur, if another electrical device is added to the electrical conductor 3. In particular, the electrical connector 1 can further comprise an assignments providing unit 13 for providing assignments between a) at least one of determination procedures for determining diagnostic information and indication procedures for indicating diagnostic information and b) conditions, and a condition providing unit 14 for providing an actual condition, wherein at least one of the diagnostic information providing unit 6 and the indicator 7 is adapted to perform a determination procedure and an indication procedure, respectively, in accordance with the provided actual condition and the provided assignments. The assignments providing unit 13 can be a storing unit in which predefined assignments are stored already, or a receiving unit for receiving the assignments via a wired or wireless data connection. The condition providing unit 14 can be a measuring unit for measuring the respective actual condition. The condition is, for example, an overload condition at the electrical conductor 3 to which the electrical connector 1 is connected. The condition providing unit 14 can be integrated with the diagnostic information providing unit 6 such that the same unit, in particular, the same electrical circuit, is used for providing the diagnostic information and for providing the actual condition. In an embodiment, the assignments define which diagnostic information has to be determined by the diagnostic information providing unit 6 and/or which diagnostic information has to be indicated by the indicator 7, if the condition providing unit 14 determines an overload condition.

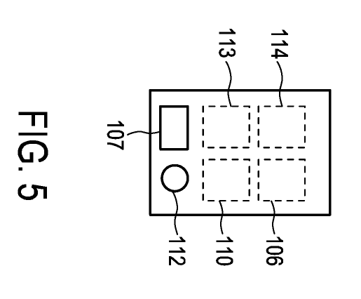

FIG. 4 shows schematically and exemplarily a further embodiment of an electrical connector 101 for connecting an electrical device to an electrical conductor 103 for powering the electrical device with DC voltage. A DC voltage source is electrically connected to the electrical conductor 103 via a cable 105 and a feed connector 104. The electrical conductor 103, the feed connector 104, the cable 105 and the DC voltage source are similar to the electrical conductor 3, the feed connector 4, the cable 5 and the DC voltage source 8 described above with reference to FIGS. 1 and 2. Moreover, also in this embodiment the electrical connector comprises a diagnostic information providing unit 106, an indicator 107, an internal power supply like a battery 110, an input unit 112, an assignments providing unit 113 and a condition providing unit 114 as schematically and exemplarily shown in FIG. 5. These elements of the electrical connector 101 are similar to the corresponding elements of the electrical connector 1 described above with reference to FIGS. 2 and 3.

However, in this embodiment the electrical connector 101 is not connected with the electrical device 109 via a cable, but the electrical connector is integrated into the electrical device 109 being, in this embodiment, a lamp. In particular, the electrical connector 101 is integrated into the housing 120 of the lamp 109. For instance, the electrical connector 101 can be mounted to at least one side of the housing 120 of the lamp 109, wherein preferentially electrical conductors like electrical wires are arranged within the electrical connector 101 such that the DC voltage applied to the electrical conductor 103 is applied to the lamp 109.

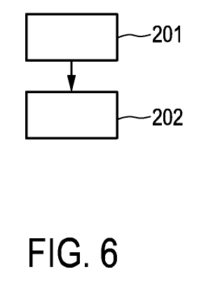

In the following a method for providing diagnostic information regarding an electrical connection between an electrical device and an electrical conductor for powering the electrical device with DC voltage by an electrical connector will exemplarily be described with reference to a flowchart shown in FIG. 6.

In step 201, the diagnostic information providing unit provides diagnostic information about the connection between the electrical device and the electrical conductor. For instance, the diagnostic information providing unit can determine whether the polarity is correct and/or whether sufficient power is available. In step 202, the determined diagnostic information is indicated by an indicator. For instance, if the polarity is correct and sufficient power is available, the indicator can show a green light, and otherwise the indicator can show a red light.

The electrical conductors are preferentially electrical conductors in accordance with the EMerge standard. These electrical conductors are preferentially power rails, which can also be called bus bars. The power rails can carry a maximum load in terms of power dissipation, which is preferentially defined by the EMerge standard and safety regulations. However, generally it is still possible to physically attach loads, i.e. electrical devices, to the power rail, which total current/voltage/power consumption would exceed the specified maximum load. Safety features are in place, in order to shut down the power rail in such a case, but it is better to prevent the system for shut down after installation as it is possible by using the electrical connectors described above with reference to FIGS. 1 to 5. For instance, the electrical connectors described above with reference to FIGS. 1 to 5 can be adapted to determine whether the total current/voltage/power consumption would exceed the specified maximum load and to indicate this to an installer.

The electrical devices to be attached to the electrical conductor can be polarity sensitive. In the prior art there is mechanically no safety feature in place, neither on the power rail nor on the electrical connector, which could prevent loads to be connected in the wrong manner in terms of polarity. However, the electrical connector described above with reference to FIGS. 1 to 5 allows performing a polarity check and indicating whether the polarity is correct or not.

The electrical devices to be connected by using the electrical connector can be, for instance, a lamp like a fluorescent lamp, a light emitting diode, a sensor, a game console, et cetera. In an embodiment, the electrical device is a light emitting lighting load with a minimum of hardware, wherein preferentially the electrical device does not comprise a rectifier bridge.

The DC power distribution systems described above with reference to FIGS. 1 to 5 are preferentially low voltage DC power distribution systems, which are adapted to be used in commercial buildings. For instance, they can be low voltage DC ceiling grid systems for distributing the DC voltage among electrical devices located at the ceiling like lamps or sensors. The different components of the DC power distribution systems are preferentially in line with the EMerge standard.

The DC power distribution systems comprise preferentially a power rail being standardized in accordance with the EMerge standard, wherein loads like lighting fixtures are attached to the power rail, to be powered and, if at the ceiling, to be fixed to a ceiling grid. The electrical connectors described above with reference to FIGS. 1 to 5 are preferentially adapted to make immediately clear to installers, if hardware is installed correctly, wherein the loads power-rail connector, i.e. the respective electrical connector, is equipped with feedback means, i.e. an indicator, which may comprise light emitting diodes or other optical or acoustical indication means, in order to—inter alia—indicate polarity correctness and/or power rail status to the user being preferentially an installer.

Although in the above described embodiments the diagnostic information providing unit and the indicator are adapted to determine and indicate certain diagnostic information, in other embodiments the diagnostic information providing unit and the indicator can also be adapted to provide other diagnostic information about a connection between an electrical device and an electrical conductor.

Although in an above described embodiment it is indicated that an installation of an electrical device by using an electrical connector has been completed successfully, if the polarity is correct and sufficient power is available, in other embodiments alternative and/or additional diagnostic information can be compared with predefined installation completed conditions, in order to determine whether the installation has been completed successfully.

For power check and position on the power rail communication can be used. A communication device can be built into the feed 4, 104, in order to measure a distance between the electrical connector 1, 101 and the feed 4, 104. The feed 4, 104 can also be adapted to gather information about other loads connected to the power rail 3, 103, in order to give proper feedback on maximum power indication to the indicator 7, 107.

Although in the above described embodiments the diagnosis functionality is part of an electrical connector, in another embodiment the diagnosis functionality may also be provided by a separate apparatus being a diagnosis apparatus that is not adapted for connecting an electrical device to, for instance, a power rail. Regarding the diagnosis functionality the diagnosis apparatus can be similar to the above described electrical connectors. However, as already mentioned above, the diagnosis apparatus is not adapted to connect an electrical device to, for instance, a power rail.

Other variations to the disclosed embodiments can be understood and effected by those skilled in the art in practicing the claimed invention, from a study of the drawings, the disclosure, and the appended claims.

In the claims, the word “comprising” does not exclude other elements or steps, and the indefinite article “a” or “an” does not exclude a plurality.

A single unit or device may fulfill the functions of several items recited in the claims. The mere fact that certain measures are recited in mutually different dependent claims does not indicate that a combination of these measures cannot be used to advantage.

Operations like the determination of diagnostic information, for instance, checking for polarity correctness and power availability, determining an actual condition, indicating the determined diagnostic information, triggering certain actions depending on an actual condition, et cetera performed by one or several units or devices can be performed by any other number of units or devices. These operations and/or the control of the electrical connector in accordance with the method for providing diagnostic information and/or the control of the diagnosis apparatus in accordance with the method for providing diagnostic information can be implemented as program code means of a computer program and/or as dedicated hardware.

A computer program may be stored/distributed on a suitable medium, such as an optical storage medium or a solid-state medium, supplied together with or as part of other hardware, but may also be distributed in other forms, such as via the Internet or other wired or wireless telecommunication systems.

Any reference signs in the claims should not be construed as limiting the scope.

1. An electrical connector for connecting an electrical device to an electrical conductor for powering the electrical device with DC voltage, the electrical connector comprising:
a diagnostic information providing unit for providing diagnostic information about a connection between the electrical device and the electrical conductor, and
an indicator for indicating the determined diagnostic information
wherein
the diagnostic information providing unit is adapted to determine diagnostic information being indicative of at least one of: polarity correctness, power availability, power losses, correctness of voltage level, and wherein
the electrical conductor is electrically connected to a DC voltage source, which is adapted to be switched off, if an overload condition is detected,
the diagnostic information providing unit is adapted to check whether a 0 V condition is present on the electrical conductor, after an electrical load has been applied to the electrical conductor, the load corresponding to the power requested by the electrical device to be connected by the electrical conductor, and to determine the power availability based on whether the 0 V condition is present.

2. (canceled)

3. The electrical connector as defined in claim 1, wherein the indicator is adapted to indicate that an installation of the electrical connector has been completed successfully, if the diagnostic information meets predefined installation completed conditions.

4. (canceled)

5. The electrical connector as defined in claim 1, wherein the diagnostic information providing unit is adapted to determine the power availability based on a measurement of an increase of a total current on the electrical conductor and a detection of overcurrent.

6. The electrical connector as defined in claim 5, wherein the diagnostic information providing unit is adapted to measure the current magnetically by measuring a magnetic field strength at a predefined distance from the electrical conductor.

7. The electrical connector as defined in claim 1, wherein the electrical connector comprises a power supply for supplying power to the diagnostic information providing unit and the indicator.

8. The electrical connector as defined in claim 1, wherein the electrical connector is integrated into the electrical device.

9. The electrical connector as defined in claim 1, wherein the electrical connector comprises an input unit for allowing a user to input a request for determining and indicating the diagnostic information.

10. The electrical connector as defined in claim 1, wherein the electrical connector further comprises:
an assignments providing unit for providing assignments between a) at least one of determination procedures for determining diagnostic information and indication procedures for indicating diagnostic information and b) conditions, and
a condition providing unit for providing an actual condition,
wherein at least one of the diagnostic information providing unit and the indicator are adapted to perform a determination procedure and an indication procedure, respectively, in accordance with the provided actual condition and the provided assignments.

11. The electrical connector as defined in claim 1, wherein the indicator is adapted to optically and/or acoustically indicate the diagnostic information.

12. An electrical device to be electrically connected with an electrical conductor to be powered by DC voltage, wherein the electrical device comprises the electrical connector as defined in claim 1.

13. A diagnosis apparatus for providing diagnostic information regarding an electrical connection between an electrical device and an electrical conductor for powering the electrical device with DC voltage by an electrical connector, the diagnosis apparatus comprising:
a diagnostic information providing unit for providing diagnostic information about a connection between the electrical device and the electrical conductor, and
an indicator for indicating the determined diagnostic information wherein
the diagnostic information providing unit is adapted to determine diagnostic information being indicative of at least one of: polarity correctness, power availability, power losses, correctness of voltage level, and wherein
the electrical conductor electrically connected to a DC voltage source, which is adapted to be switched off, if an overload condition is detected,
the diagnostic information providing unit is adapted to check whether a 0 V condition is present on the electrical conductor, after an electrical load has been applied to the electrical conductor, the load corresponding to the power requested by the electrical device to be connected by the electrical conductor, and to determine the power availability based on whether the 0 V condition is present.

14. A method for providing diagnostic information regarding an electrical connection between an electrical device and an electrical conductor by an electrical connector as defined in claim 1 for powering the electrical device with DC voltage, the method including the steps of:
providing diagnostic information about a connection between the electrical device and the electrical conductor by a diagnostic information providing unit, including determining diagnostic information being indicative of at least one of: polarity correctness, power availability, power losses, correctness of voltage level, wherein when the electrical conductor is electrically connected to a DC voltage source, which is adapted to be switched off, if an overload condition is detected, providing the diagnostic information comprising checking whether a 0 V Condition is present on the electrical conductor, after an electrical load has been applied to the electrical conductor, the load corresponding to the power requested by the electrical device to be connected by the electrical conductor, and determining the power availability based on whether the 0 V condition is present, and
indicating the determined diagnostic information by an indicator.

15. A non-transitory computer readable medium programmed with computer readable code for providing diagnostic information regarding an electrical connection between an electrical device and an electrical conductor by an electrical connector as defined in claim 1 for powering the electrical device with DC voltage, the computer program readable code that upon execution by a processor causes the processor to: determine diagnostic information being indicative of at least one of: polarity correctness, power availability, power losses, correctness of voltage level, wherein when the electrical conductor is electrically connected to a DC voltage source, which is adapted to be switched off, if an overload condition is detected,
check whether a 0 V condition is present on the electrical conductor, after an electrical load has been applied to the electrical conductor, the load corresponding to the power requested by the electrical device to be connected by the electrical conductor,
determine the power availability based on whether the 0 V condition is present, and
indicate the determine diagnostic information by an indicator.
